(19) United States
(12) Patent Application Publication
(10) Pub. No.: US 2023/0176091 A1
(43) Pub. Date: Jun. 8, 2023

(54) PROBE CARD

(71) Applicant: YOKOWO CO., LTD., Kita-ku, Tokyo (JP)

(72) Inventor: Hiroki YAMASHITA, Tomioka-shi, Gunma (JP)

(73) Assignee: YOKOWO CO., LTD., Kita-ku, Tokyo (JP)

(21) Appl. No.: 17/921,656

(22) PCT Filed: May 13, 2021
(86) PCT No.: PCT/JP2021/018173

§ 371 Date: Oct. 27, 2022

(30) Foreign Application Priority Data
Jun. 17, 2020 (JP) 2020-104309

(51) Int. Cl. G01R 1/073

(52) U.S. Cl. CPC G01R 1/07342

(57) ABSTRACT

A probe card (10) includes a flexible substrate (114) and a rigid substrate (120). The flexible substrate (114) contacts an inspection object. The rigid substrate (120) is electrically connected to the flexible substrate (114). The flexible substrate (114) is located on a side of the rigid substrate (120) where the inspection object is located in a direction perpendicular to the rigid substrate (120).

### TECHNICAL FIELD

The present invention relates to a probe card.

### BACKGROUND ART

A probe card attachable to an inspection device may be used in order to inspect electrical characteristic of an inspection object, for example, an electronic device such as an integrated circuit (IC). For example, as described in Patent Document 1, a probe card includes a contactor having a flexible substrate provided with a contact portion for contacting an inspection object. The flexible substrate is electrically connected to a rigid substrate. Most part of the flexible substrate is located on a side of the rigid substrate where the inspection object is located in a direction perpendicular to the rigid substrate.

### Related Document

### Patent Document

[Patent Document 1] Japanese Unexamined Patent Publication No. 2019-109101

### SUMMARY OF THE INVENTION

### Technical Problem

In the probe card of Patent Document 1, a part of the flexible substrate is located on a side of the rigid substrate opposite to the side where the inspection object is located in the direction perpendicular to the rigid substrate. Accordingly, in order to replace the contactor having the flexible substrate, it is necessary to remove the entire probe card including the rigid substrate from the inspection device. However, the work of removing the entire probe card from the inspection device may be complicated.

An example of an object of the present invention is to facilitate replacement of a contactor having a flexible substrate. Another object of the present invention will become apparent from the description of the present specification.

### Solution to Problem

One aspect of the present invention is a probe card including:
a flexible substrate for contacting an inspection object; and
a rigid substrate electrically connected to the flexible substrate,
in which the flexible substrate is located on a side of the rigid substrate where the inspection object is located in a direction perpendicular to the rigid substrate.

### Advantageous Effects of Invention

According to the above aspect of the present invention, replacement of a contactor having the flexible substrate can be facilitated.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a perspective view of a probe card according to an embodiment.

FIG. 2 is a view showing a cross-section passing through line A-A′ of FIG. 1 in a vertical direction.

FIG. 3 is an enlarged view of a contactor of FIG. 2 and surroundings thereof.

FIG. 4 is a view illustrating an example of a method of replacing the contactor.

FIG. 5 is a view illustrating an example of the method of replacing the contactor.

FIG. 6 is a view illustrating an example of the method of replacing the contactor.

### DESCRIPTION OF EMBODIMENTS

Hereinafter, an embodiment of the present invention will be described with reference to the drawings. In all drawings, the same constituent elements are designated by the same reference numerals, and the description thereof will not be repeated as appropriate.

In the present specification, ordinal numbers, such as “first”, “second”, and “third”, are added in order only to distinguish the configurations having the same names unless otherwise specified, and do not imply specific features of the configurations, such as order and importance.

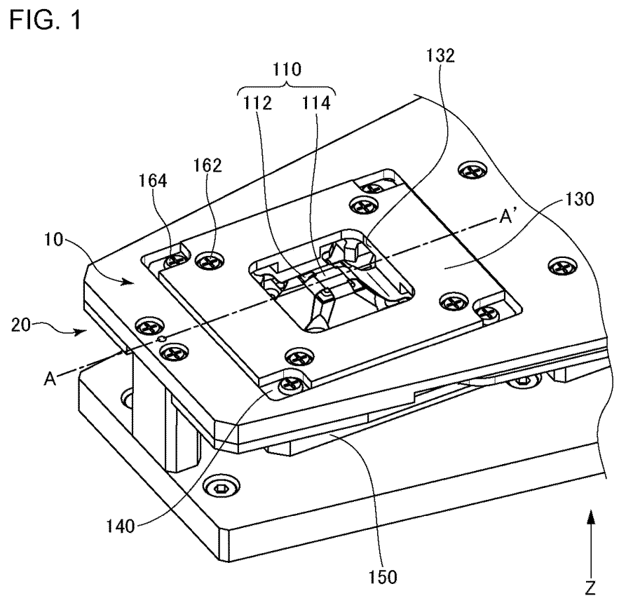

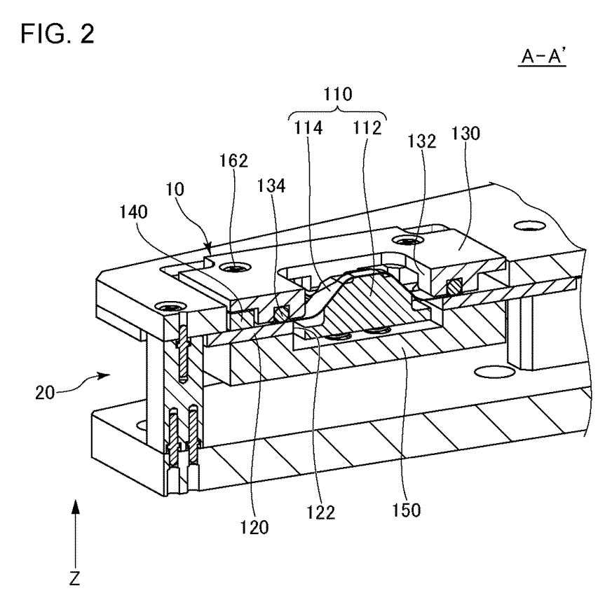

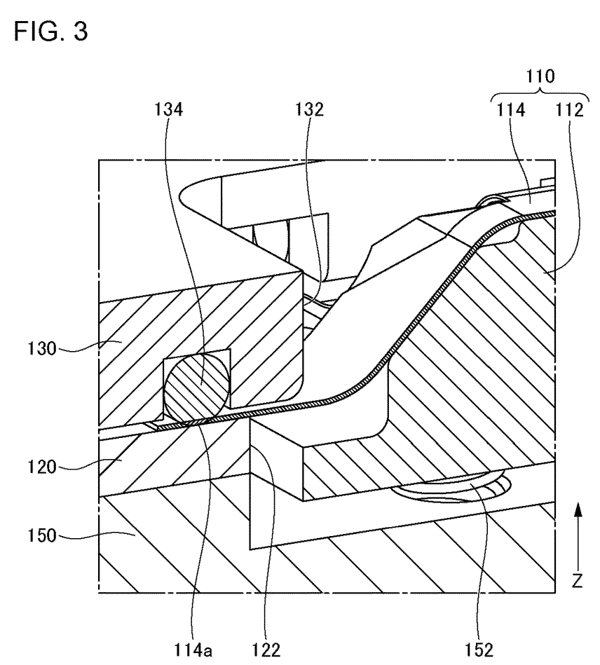

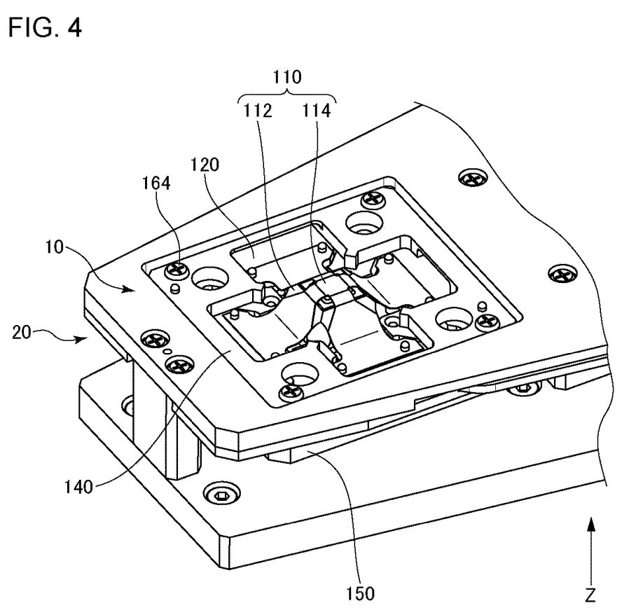

FIG. 1 is a perspective view of a probe card 10 according to the embodiment. FIG. 2 is a view showing a cross-section passing through line A-A′ of FIG. 1 in a vertical direction Z. FIG. 3 is an enlarged view of a contactor 110 of FIG. 2 and surroundings thereof. In FIGS. 1 to 3, the vertical direction Z is a direction perpendicular to a rigid substrate 120, which will be described later. The vertical direction Z is parallel to a thickness direction of the rigid substrate 120. A positive direction of the vertical direction Z, which is a direction indicated by an arrow indicating the vertical direction Z, indicates an up direction of the vertical direction Z. In particular, in the present embodiment, the positive direction of the vertical direction Z is a direction from a side where the rigid substrate 120 is located toward a side where a contact portion of a flexible substrate 114, which will be described later, is located. A negative direction of the vertical direction Z, which is a direction opposite to the direction indicated by the arrow indicating the vertical direction Z, indicates a down direction of the vertical direction Z. In particular, in the present embodiment, the negative direction of the vertical direction Z is a direction from the side where the contact portion of the flexible substrate 114 is located toward the side where the rigid substrate 120 is located. The same applies to FIGS. 4 to 6, which will be described later, with regard to the vertical direction Z.

The structure of the probe card 10 will be described with reference to FIGS. 1 to 3.

The probe card 10 is attached to an inspection device 20. The probe card 10 includes the contactor 110, the rigid substrate 120, a pressing block 130, a retainer 140, and a nut plate 150.

The contactor 110 has a pedestal block 112 and the flexible substrate 114. Although details will be described later, in the contactor 110, the contact portion (not shown) located at the upper end of the flexible substrate 114 contacts an inspection object of the inspection device 20, for example, an electronic device, such as an IC. The pedestal block 112 is, for example, a metal block or a resin block. At least a part of the upper surface of the pedestal block 112 is located above the upper surface of the rigid substrate 120 in the vertical direction Z. The flexible substrate 114 is, for example, a flexible printed circuit (FPC). The flexible substrate 114 is located above the pedestal block 112 in the vertical direction Z. The flexible substrate 114 is curved along the upper surface of the pedestal block 112 in a first opening 122 of the rigid substrate 120 and a second opening 132 of the pressing block 130, which will be described later.

The rigid substrate 120 is, for example, a printed circuit board (PCB). As shown in FIGS. 2 and 3, the rigid substrate 120 defines the first opening 122 that penetrates the rigid substrate 120 in the vertical direction Z. The pedestal block 112 and a part of the flexible substrate 114 are located in the first opening 122. The rigid substrate 120 is electrically connected to the flexible substrate 114.

The pressing block 130 is, for example, a metal block or a resin block. The pressing block 130 is fixed to the rigid substrate 120 by a first fastener 162. Specifically, the pressing block 130 is located above the rigid substrate 120 in the vertical direction Z. The first fastener 162 penetrates the pressing block 130 in the negative direction of the vertical direction Z. The tip end of the first fastener 162, that is, the lower end of the first fastener 162 in the vertical direction Z is attached to the rigid substrate 120. In the present embodiment, the first fastener 162 is a screw. However, the first fastener 162 may be a fastener other than the screw, such as a bolt. The pressing block 130 defines the second opening 132 that penetrates the pressing block 130 in the vertical direction Z. The pedestal block 112 and a part of the flexible substrate 114 are located in the second opening 132.

The pressing block 130 presses the flexible substrate 114 against the rigid substrate 120 in the negative direction of the vertical direction Z. Thus, the pressing block 130 prevents the flexible substrate 114 from being spaced apart from the rigid substrate 120. Specifically, as shown in FIGS. 2 and 3, a recessed portion into which a pressing elastic material 134 is inserted is formed on the lower surface of the pressing block 130. The pressing elastic material 134 is, for example, rubber, such as silicone rubber. The pressing elastic material 134 presses the flexible substrate 114 against the rigid substrate 120 in the negative direction of the vertical direction Z. At least a part of the pressing block 130 itself may contact the flexible substrate 114 without using the pressing elastic material 134, whereby the pressing block 130 may press the flexible substrate 114.

As shown in FIG. 3, when viewed from the positive direction of the vertical direction Z, at least a part of the flexible substrate 114 overlaps a pressing portion of the pressing block 130, that is, the pressing elastic material 134. Accordingly, the flexible substrate 114 is pressable against the rigid substrate 120 by the pressing elastic material 134. The flexible substrate 114 has a connection region 114a located at a position overlapping the pressing elastic material 134 when viewed from the positive direction of the vertical direction Z. The flexible substrate 114 is electrically connected to the rigid substrate 120 through the connection region 114a at a position where the pressing block 130 presses the flexible substrate 114.

The connection region 114a defines at least one through-hole in the vertical direction Z. A conductive material, such as metal, embedded in the through-hole can function as a connecting member for electrically connecting the flexible substrate 114 and the rigid substrate 120. The conductive material embedded in the through-hole can also function as a stopper member for preventing the pressing block 130 such as the pressing elastic material 134 from crushing a portion of the flexible substrate 114 (the connection region 114a in the present embodiment) pressed by the pressing block 130 such as the pressing elastic material 134. Even if the connecting member is provided at a position different from the position where the pressing block 130 presses the flexible substrate 114, it is preferable that the stopper member is provided in order to prevent crushing of the portion of the flexible substrate 114 pressed by the pressing block 130. If the stopper member is provided and the connecting member is provided at a position different from the position where the pressing block 130 presses the flexible substrate 114, the electrical characteristic of the probe card 10 may decrease due to the stopper member, and the inspection result of the inspection device 20 may be inaccurate. On the other hand, according to the present embodiment, the position where the connecting member is provided and the position where the stopper member is provided coincide with each other. Accordingly, it is possible to restrain decrease of the electrical characteristic of the probe card 10 due to the stopper member. However, the position where the connecting member is provided and the position where the stopper member is provided may be offset from each other.

The pressing portion of the pressing block 130 is a portion of the pressing block 130 for contacting the rigid substrate 120. In the present embodiment, the pressing portion of the pressing block 130 is the pressing elastic material 134. For example, if the pressing block 130 does not have the pressing elastic material 134, the pressing portion of the pressing block 130 is a portion of the pressing block 130 for contacting the rigid substrate 120.

The retainer 140 is, for example, a metal plate or a resin plate. The retainer 140 is fixed to the rigid substrate 120 by a second fastener 164. Specifically, the retainer 140 is located above the rigid substrate 120 in the vertical direction Z. The second fastener 164 penetrates the retainer 140 in the negative direction of the vertical direction Z. The tip end of the second fastener 164, that is, the lower end of the second fastener 164 in the vertical direction Z is attached to the rigid substrate 120. In the present embodiment, the second fastener 164 is a screw. However, the second fastener 164 may be a fastener other than the screw, such as a bolt.

The nut plate 150 is, for example, a metal plate or a resin plate. The nut plate 150 is located below the flexible substrate 114 and the rigid substrate 120 in the vertical direction Z. The pedestal block 112 is biased upward in the vertical direction Z by an elastic body 152 attached to the nut plate 150. In the present embodiment, the elastic body 152 is a spring. However, the elastic body 152 may be an elastic body other than the spring, such as rubber. The elastic body 152 allows the contact portion of the contactor 110 to contact the inspection object with a biasing force being applied to the inspection object of the inspection device 20.

FIGS. 4 to 6 are views illustrating an example of a method of replacing the contactor 110. In the method shown in FIGS. 4 to 6, the contactor 110 is removed from the state shown in FIG. 1 as follows.

First, in the state shown in FIG. 1, the head of the first fastener 162, that is, the screw head of the screw is directed upward in the vertical direction Z. Similarly, the head of the second fastener 164, that is, the screw head of the screw, is directed upward in the vertical direction Z. In FIGS. 4 to 6, the contactor 110 can be removed with the head of the first fastener 162 and the head of the second fastener 164, and the contact portion of the flexible substrate 114 being directed in the same direction, that is, upward in the vertical direction Z. In this case, damage of the contact portion of the flexible substrate 114 can be restrained, as compared with a case where the head of the first fastener 162 and the head of the second fastener 164, and the contact portion of the flexible substrate 114 are directed in different directions, for example, as compared with a case where the head of the first fastener 162 and the head of the second fastener 164 are directed upward in the vertical direction Z, and the contact portion of the flexible substrate 114 is directed downward in the vertical direction Z.

As shown in FIG. 4, the first fastener 162 shown in FIG. 1 is removed from the state shown in FIG. 1, whereby the pressing block 130 shown in FIG. 1 is removed from the rigid substrate 120.

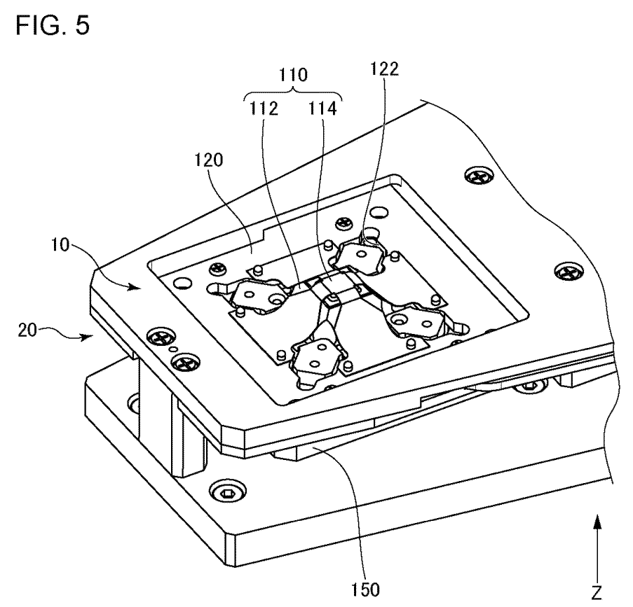

Then, as shown in FIG. 5, the second fastener 164 shown in FIG. 4 is removed, whereby the retainer 140 shown in FIG. 4 is removed from the rigid substrate 120.

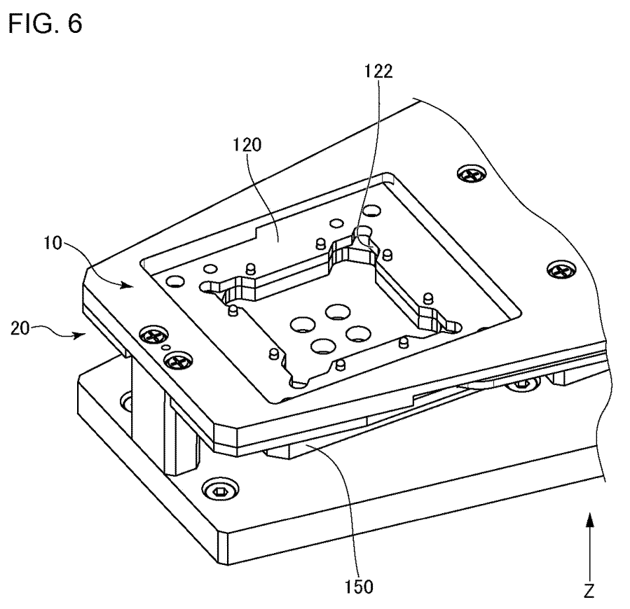

Then, as shown in FIG. 6, the contactor 110 shown in FIG. 5 is removed.

The case where a new contactor 110 is assembled to the probe card 10 is as follows. That is, first, the retainer 140 is fixed to the rigid substrate 120 by the second fastener 164 with the contactor 110 being attached to the rigid substrate 120 and the nut plate 150. Then, the pressing block 130 is fixed to the rigid substrate 120 by the first fastener 162.

According to the above method, the flexible substrate 114 is located on the side of the rigid substrate 120 where the inspection object is located, that is, the side of the rigid substrate 120 where the contact portion of the flexible substrate 114 is located, in the direction perpendicular to the rigid substrate 120. Accordingly, when replacing the contactor 110, it is not necessary to remove the rigid substrate 120 from the inspection device 20. In this case, the replacement of the contactor 110 as compared can be facilitated with a case where the entire probe card 10 including the rigid substrate 120 is removed from the inspection device 20.

Further, the pressing block 130 is located on the side of the rigid substrate 120 where the inspection object is located, that is, the side of the rigid substrate 120 where the contact portion of the flexible substrate 114 is located, in the direction perpendicular to the rigid substrate 120. Accordingly, when removing the pressing block 130, it is not necessary to remove the rigid substrate 120 from the inspection device 20. In this case, the removal of the pressing block 130 can be facilitated as compared with the case where the entire probe card 10 including the rigid substrate 120 is removed from the inspection device 20.

In the present embodiment, as shown in FIGS. 1 and 2, the probe card 10 inspects the inspection object of the inspection device 20 with the contact portion of the contactor 110 being directed upward in the vertical direction Z. Specifically, the inspection object is brought close to the contactor 110 from above the contactor 110 in the vertical direction Z. Thus, an electrode of the inspection object, such as a bump, is brought into contact with the contact portion of the contactor 110 so that the probe card 10 inspects the inspection object. However, the probe card 10 may inspect the inspection object with the contact portion of the contactor 110 being directed in a direction different from upward in the vertical direction Z, such as downward in the vertical direction Z.

Although the embodiment of the present invention has been described above with reference to the drawings, these are examples of the present invention, and various configurations other than the above can be adopted.

According to the present specification, the following aspects are provided.

### Aspect 1

Aspect 1 is a probe card including:
a flexible substrate for contacting an inspection object; and
a rigid substrate electrically connected to the flexible substrate,
in which the flexible substrate is located on a side of the rigid substrate where the inspection object is located in a direction perpendicular to the rigid substrate.

According to aspect 1, when replacing the contactor having the flexible substrate, it is not necessary to remove the rigid substrate from the inspection device to which the probe card is attached. In this case, the replacement of the contactor having the flexible substrate can be facilitated as compared with a case where the entire probe card including the rigid substrate is removed from the inspection device.

### Aspect 2

Aspect 2 is the probe card according to aspect 1, further including:

a pressing block pressing the flexible substrate against the rigid substrate in a direction from the side where the inspection object is located to a side where the rigid substrate is located.

According to aspect 2, the pressing block prevents the flexible substrate from being spaced apart from the rigid substrate. Further, according to aspect 2, the pressing block is located on the side of the rigid substrate where the inspection object is located in the direction perpendicular to the rigid substrate. Accordingly, when removing the pressing block, it is not necessary to remove the rigid substrate from the inspection device. In this case, the removal of the pressing block can be facilitated as compared with the case where the entire probe card including the rigid substrate is removed from the inspection device.

### Aspect 3

Aspect 3 is the probe card according to aspect 2,
in which the flexible substrate is electrically connected to the rigid substrate at a postition where the pressing block presses the flexible substrate.

According to aspect 3, it is not necessary to provide the stopper member for preventing the pressing block from crushing the portion of the flexible substrate pressed by the pressing block, in addition to the connecting member for electrically connecting the flexible substrate and the rigid substrate. Accordingly, it is possible to restrain decrease of the electrical characteristic of the probe card due to the stopper member provided in addition to the connecting member.

### Aspect 4

Aspect 4 is the probe card according to aspect 2 or 3, further including:
a fastener penetrating the pressing block in the direction from the side where the inspection object is located to the side where the rigid substrate is located, the fastener being attached to the rigid substrate

According to aspect 4, the contactor can be removed with the head of the fastener and the contact portion of the flexible substrate for contacting the inspection object being directed in the same direction. In this case, damage of the contact portion of the flexible substrate can be restrained as compared with a case where the head of the fastener and the contact portion of the flexible substrate are directed in different directions.

This application claims priority based on Japanese Patent Application No. 2020-104309, filed Jun. 17, 2020, the entire disclosure of which is incorporated herein.

REFERENCE SIGNS LIST

| | |
|---|---|
| 10 | probe card |
| 20 | inspection device |
| 110 | contactor |
| 112 | pedestal block |
| 114 | flexible substrate |
| 114 a | connection region |
| 120 | rigid substrate |
| 122 | first opening |
| 130 | pressing block |
| 132 | second opening |
| 134 | pressing elastic material |
| 140 | retainer |
| 150 | nut plate |
| 152 | elastic body |
| 162 | first fastener |
| 164 | second fastener |
| Z | vertical direction |

1. A probe card comprising:
a flexible substrate for contacting an inspection object; and
a rigid substrate electrically connected to the flexible substrate;
wherein the flexible substrate is located on a side of the rigid substrate where the inspection object is located in a direction perpendicular to the rigid substrate.

2. The probe card according to claim 1, further comprising:
a pressing block pressing the flexible substrate against the rigid substrate in a direction from the side where the inspection object is located to a side where the rigid substrate is located.

3. The probe card according to claim 2,
wherein the flexible substrate is electrically connected to the rigid substrate at a position where the pressing block presses the flexible substrate.

4. The probe card according to claim 2 , further comprising:
a fastener penetrating the pressing block in the direction from the side where the inspection object is located to the side where the rigid substrate is located, the fastener being attached to the rigid substrate.

5. The probe card according to claim 3, further comprising:
a fastener penetrating the pressing block in the direction from the side where the inspection object is located to the side where the rigid substrate is located, the fastener being attached to the rigid substrate.
